(19) United States
(12) Patent Application Publication
(10) Pub. No.: US 2010/0080673 A1
(43) Pub. Date: Apr. 1, 2010

(54) TRANSPORTING DEVICE FOR A VACUUM PROCESSING APPARATUS, DRIVE DEVICE FOR A COMPONENT OF A VACUUM PROCESSING APPARATUS, AND A VACUUM PROCESSING APPARATUS

(75) Inventors: Hubertus VON DER WAYDBRINK, Dresden (DE); Udo WILLKOMMEN, Dresden (DE); Michael HENTSCHEL, Dresden (DE); Marco KENNE, Dresden (DE)

Correspondence Address: HESLIN ROTHENBERG FARLEY & MESITI PC, 5 COLUMBIA CIRCLE, ALBANY, NY, 12203, US

(73) Assignee: VON ARDENNE ANLAGENTECHNIK GMBH, Dresden (DE)

(21) Appl. No.: 12/569,276

(22) Filed: Sep. 29, 2009

(30) Foreign Application Priority Data
Sep. 29, 2008 (DE) 10 2008 049 302.3
Jan. 23, 2009 (DE) 10 2009 005 966.0

(51) Int. Cl. H01L 21/677; B65G 15/48; B65G 39/10; B65G 37/00

(52) U.S. Cl. 414/222.01; 198/846; 198/842; 198/347.1

(57) ABSTRACT

A transport device for a vacuum processing system, a drive unit for high temperature processes in vacuum processing systems, and a vacuum processing system employ a drive unit which operates without the polygonal effect, can be connected endlessly, is suitable for high temperatures, is insensitive to radiation heat, does not generate degassing and does not need a lubricant. The drive unit includes a traction element, guided around at least two deflecting rollers. The traction element is a continuous metal strip.

The invention relates to embodiments of a transport device for a vacuum processing system, a drive unit for high temperature processes in vacuum processing systems, and a vacuum processing system with such a transport device and/or with such a drive unit.

In this context a vacuum processing system is defined as a system for carrying out substrate vacuum treatments, such as etching or coating processes. Such systems usually exhibit both a vacuum chamber as well as several treatment devices, like coating sources or etching equipment. Other system components, like transport devices, storage units, heating systems, cooling systems, etc.—some of which exhibit a drive unit—may also be provided. The patent application WO 2008/003792 A2 discloses, for example, a transport device for tubular substrates inside a vacuum processing system with a drive unit. Some of the additional system components can also be arranged totally or partially on the atmospheric side, for example, at the inlet or outlet of the vacuum processing system.

High temperature processes are defined hereinafter as those processes that run at temperatures that are significantly above the engineering standard temperature of 20° C., at which industrial materials of substrates—for example, synthetic plastic materials—that are to be coated are negatively affected by softening and/or extreme thermal expansion. The drive unit is particularly well suited for such processes under atmospheric conditions, and also in vacuum. However, it is self-evident that its application is not limited to high temperature conditions and that the drive unit can also be employed under other environmental conditions.

In order to transport substrates through vacuum coating systems, there exist transport devices that achieve the transport of substrates inside the vacuum chamber and/or through the vacuum chamber. Such transport devices can comprise, for example, a plurality of transport rolls, which are arranged in succession in the direction of transport of the substrates and on which the substrates are placed so as to lie flat—either singly or in groups of two or a plurality of substrates in parallel next to one another. Then the single substrates and/or the groups of substrates, lying side by side, are moved through the vacuum chamber by driving the transport rolls sequentially—that is, one after another. Examples of such transport devices are described, for example, in the DE 10 2004 021 734 A1.

The use of storage units is also known, especially in connection with the diffusion treatment and layer deposition of wafers and glass substrates for liquid crystal displays. For example, the U.S. Pat. No. 5,512,320 describes vacuum processing systems, in which the glass substrates are deposited in storage cassettes before and after the treatment. First, several substrates are deposited in one storage cassette, and the storage cassette is made available inside the vacuum processing system. In contrast, the actual vacuum treatment, in which a variety of layers are deposited on the substrates, takes place sequentially. That is, a single substrate is removed from the storage cassette and transferred into the treatment zone of the vacuum processing system. Following completion of the treatment, the substrate is removed from the treatment zone and deposited again in a storage cassette. Then all of the substrates that are temporarily stored in the storage cassette are removed in their entirety from the vacuum processing system. In contrast, the U.S. Pat. No. 3,183,130 discloses a system for the treatment of a plurality of wafers in a diffusion furnace, which operates in the so-called batch mode. In this case the substrates are deposited in a common storage cassette, and then the storage cassette is fed into the diffusion furnace. All of the substrates are subjected jointly to the desired treatment and then removed together with the storage cassette from the diffusion furnace.

Moreover, there exist drive units, inter alia, in connection with the drive of the aforementioned transport devices, in which movements are transferred by means of traction elements, like toothed belts, arc toothed chains, roller chains or Cardan shafts with a bevel gear tooth system, to the substrates, substrate holders (carriers) or measurement instruments either directly or by way of other transport means, like transport frames, transport holders, transport rollers or transport rolls or combinations of such transport means, which in turn are driven by the traction element of the drive unit. In the case of these drive units, it is possible to detect from the beginning to the end a more or less strong polygonal effect, which is undesired in vacuum technology. As a consequence of this polygonal effect, the speed of the traction element fluctuates periodically around an average speed. Steel cables are also used in such drive units as the traction element, but have reached the engineering limits with their infinite connection and the inner friction of the strands.

Therefore, the object of the invention is to provide a transport device, which is intended for a vacuum processing system and which makes possible, especially in the case of continuous processes, in which the substrates are moved one after another through the vacuum processing system, the simultaneous treatment of multiple substrates without having to interrupt the continuous process. An additional object of the invention is to develop a drive unit, which is intended, in particular, for a system component of a vacuum processing system and which operates without the polygonal effect, can be connected endlessly, is suitable for high temperatures, is insensitive to radiation heat, does not generate degassing and does not need a lubricant—thus, is maintenance free—with the advantage that the substrate coating is absolutely uniform and homogeneous.

In order to solve these problems, embodiments of transport devices, drive units and vacuum processing systems are proposed below.

An improvement of the known drive units in terms of the aforementioned problems is achieved with the use of one or more continuously connected metal strip(s) in a drive unit for a vacuum processing system. In this context a metal strip is defined as a sheet metal strip, usually made of fine gauge sheet metal having a thickness of up to 3 mm. The ends of such a metal strip are connected together so as to form a continuous drive belt. The width of the metal strip can be adapted to the intended application, in particular, to the forces that are to be transferred, and can range from a few millimeters up to a few centimeters. It has been demonstrated that for the application cases that are anticipated here, especially suitable materials for the metal strip are predominantly stainless steel, but other metals or metal alloys can also be used.

In one embodiment the metal strips can be perforated. In this case the transport rollers, drive rollers or deflecting rollers exhibit in an advantageous manner a plurality of teeth or nubs, which are uniformly distributed over the periphery and which mesh with the perforations of the metal strip and, thus, guarantee a slip-free transfer of motion. With this drive unit transport rollers can be driven directly—with the use of perforated metal strips through the meshing of the teeth or the nubs with the perforations—from roller to roller (the metal strip envelops all of the transport, drive or deflecting rollers) or according to the pin wheel principle (the metal strip envelops only the drive and/or deflecting rollers; the transport rollers are in engagement with the outside of the upper or lower strand of the metal strip). It is possible with the aid of the tangential effect of friction to rotate or move the substrates reliably and without abrasion on the metal strip upstream of the evaporator, magnetron or other coating sources. An additional advantage of the metal belt that ought to be mentioned is that the surroundings of the vacuum are not degassed and/or contaminated in any way.

If the substrates are placed directly on the metal strip, then the described drive unit acts independently as the transport device and without the involvement of additional components. That is, the drive unit does not drive an additional system component, but rather achieves directly the transport of the substrates in or through the vacuum processing system.

The metal strip(s) may function as electrical conductors and, thus, for example, transport measurement instruments or other equipment to every position of the evacuated system and carry out measurements and/or is/are used for the purpose of applying the substrates to a desired electric potential. The proposed drive unit can also be used in an advantageous manner for other application cases, for example, for driving other system components, like vertical lift devices or vertical storage units according to the paternoster (continuous moving) lift principle, in which the substrates in the treatment zone and/or between two processing steps are temporarily stored in vacuum or under atmospheric conditions inside the vacuum processing system and/or at the inlet or outlet of the vacuum processing system.

Furthermore, the invention proposes a transport device for a vacuum processing system, which comprises at least two sequentially operating transport devices for the transport of single substrates through the vacuum processing system. Furthermore, in at least one processing zone of the vacuum processing system there is a storage unit, which is intended for receiving a plurality of substrates, and which can be loaded with substrates by an upstream sequential transport device and which can be unloaded by a downstream sequential transport device.

Moreover, a loading and/or unloading device can be provided for loading and/or unloading the storage unit, insofar as the substrates cannot be received directly by the upstream sequential transport device and transferred directly to the downstream sequential transport device.

The storage unit can exhibit, for example, at least two substrate trays. In this context at least one substrate tray can be moved back and forth between a receiving position and a storage position. Furthermore, it can be provided that the at least one substrate tray can be driven by a drive unit of the above described type.

One embodiment of the transport device provides that the at least one substrate tray can be moved in essence at right angles to the direction of motion of an upstream or a downstream transport device.

An additional embodiment of the transport device provides that the substrate tray is designed for receiving simultaneously at least two substrates. This feature is especially advantageous if the substrates are moved in groups of two or more substrates, lying side by side, through the vacuum processing system. As an alternative it can also be provided that the storage unit exhibits a plurality of stacked groups of two or more substrate trays, arranged side by side, or that two or more of the described storage units are arranged side by side in the processing zone, and that each storage unit receives one of the substrates, lying side by side.

Another embodiment can provide that at least one upstream or downstream transport device is a drive unit of the above described type.

An additional subject matter relates to an accumulator conveyor for plate shaped substrates, which can be used, for example, in a vacuum processing system for the physical-chemical surface treatment of such substrates.

In the case of a transport device for a vacuum processing system, which comprises at least two sequentially operating transport devices—that is, transport devices for the sequential transport of single substrates or groups of substrates through the vacuum processing system—wherein in at least one processing zone of the vacuum processing system there is a storage unit, which is intended for receiving a plurality of substrates, and which can be loaded with substrates from an upstream sequential transport device and which can be unloaded onto a downstream sequential transport device and which exhibits at least two substrate trays, where at least one substrate tray can be moved back and forth between a receiving position and a storage position, the invention proposes that the substrate tray comprises a frame and a plurality of drivable support elements, which are mounted in a rotatable manner, for the purpose of receiving a substrate.

For example, it can be provided that the support elements are designed as rolls. In this context rolls are elongated, cylindrical bodies. As an alternative, the support elements can be designed, for example, as rollers, of which a plurality are arranged on a shaft. In this context rollers are circular disks—that is, short, cylindrical bodies.

One embodiment proposes that the substrate tray exhibits a substrate tray area with recesses for the support elements.

A further development provides that the support elements can be moved relative to the frame in such a manner that in a first position they are arranged totally below the substrate tray area and in a second position they protrude at least partially through the recesses and over the substrate tray area.

In other words, the support elements—thus, for example, the rolls or shafts with the mounted rollers—can be displaced in the perpendicular direction—for example, raised and lowered—relative to the substrate tray area.

If a substrate tray is moved into the plane of the upstream and downstream transport device in order to load the substrate tray with a substrate, then the support elements are in a position that projects at least partially beyond the substrate tray area—that is, they are raised relative to the substrate tray area—so that they project at least partially beyond the substrate tray area. As a consequence, the substrates can be received by the support elements and moved through rotation of the support elements into a position, in which they are totally above the substrate tray area.

If the substrate tray is then moved—for example, raised or lowered—out of the transport plane of the substrates—that is, the plane of the transport devices—then the support elements can be moved into the first position, in which the support elements lie totally below the substrate tray area. As a consequence, the substrate lies directly on the substrate tray area, so that it can no longer be moved unintentionally.

If the treatment of the substrate is completed or for some other reason the substrate is transported away, then the substrate tray is moved again into the transport plane of the substrates—that is, moved into the plane of the transport devices. The support elements are moved into the second position, in which they project at least partially beyond the substrate tray area, so that the substrate no longer has any contact with the substrate tray area. As a consequence, the substrates can be transferred through rotation of the support elements to the subsequent transport device.

The proposed drive unit is explained in detail below by means of the embodiments and the related drawings.

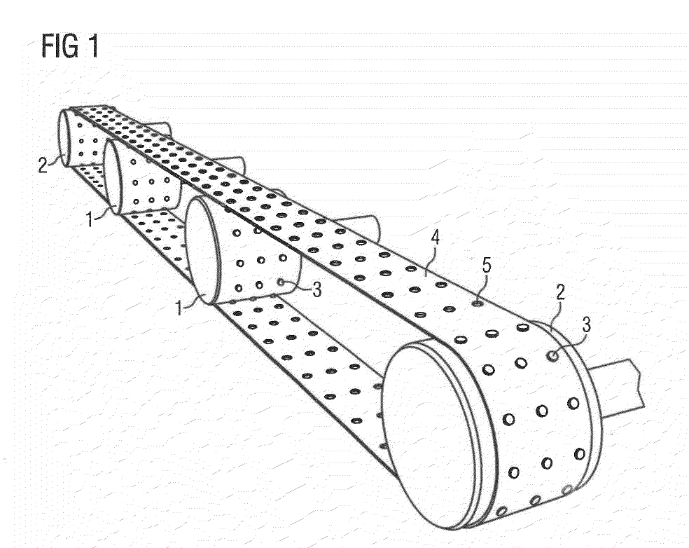

FIG. 1 depicts a first embodiment of a drive unit,

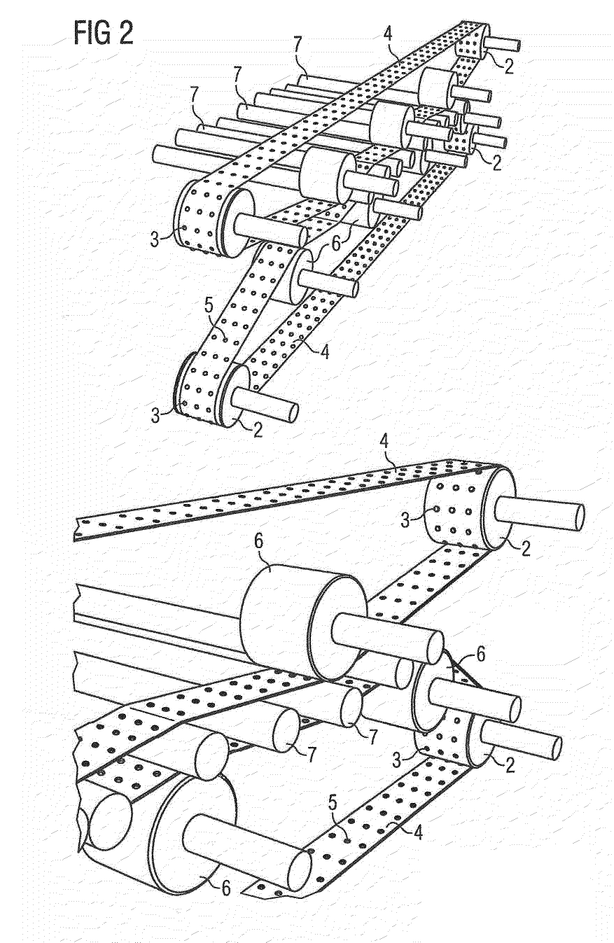

FIG. 2 depicts a second embodiment of a drive unit, and

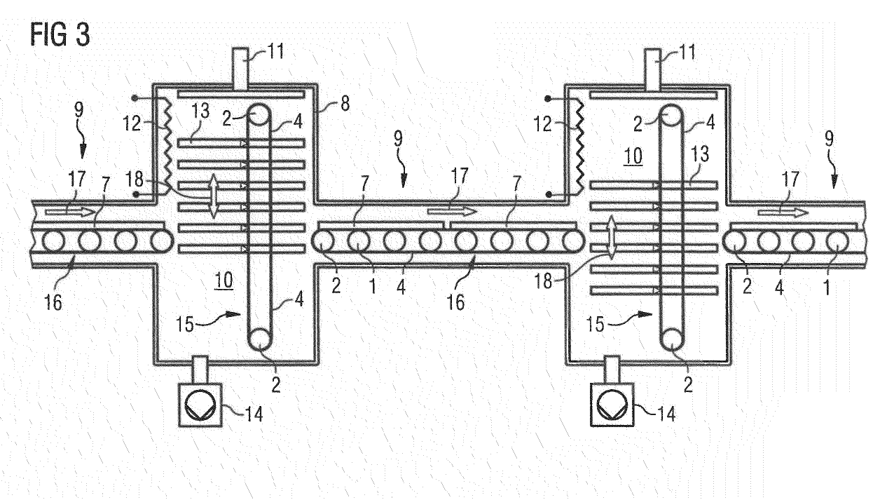

FIG. 3 is a longitudinal view of a detail of a vacuum processing system with a storage unit in each processing zone.

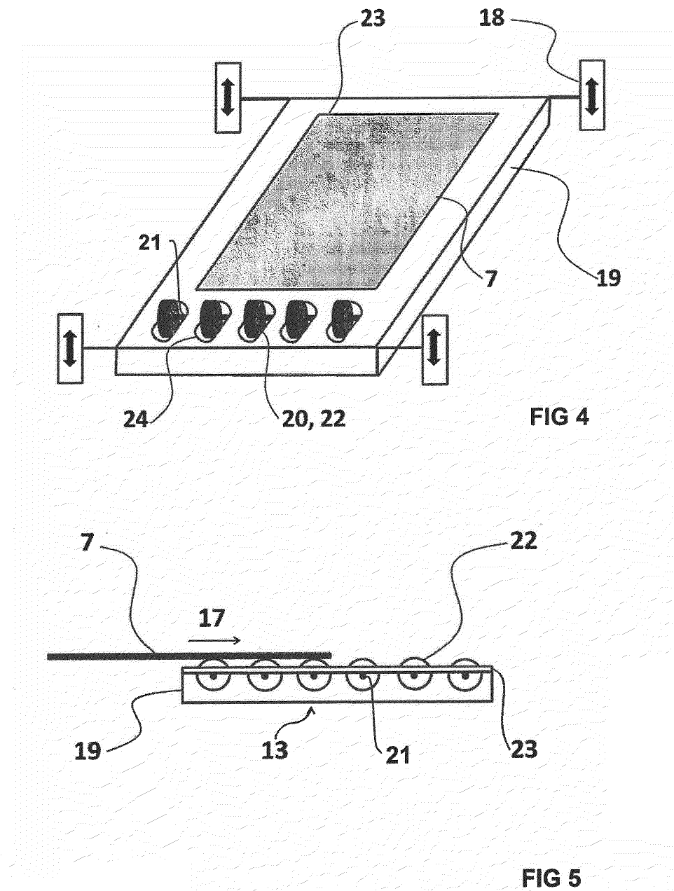

FIG. 4 depicts a substrate tray of the described type,

FIG. 5 depicts the loading of a substrate tray, and

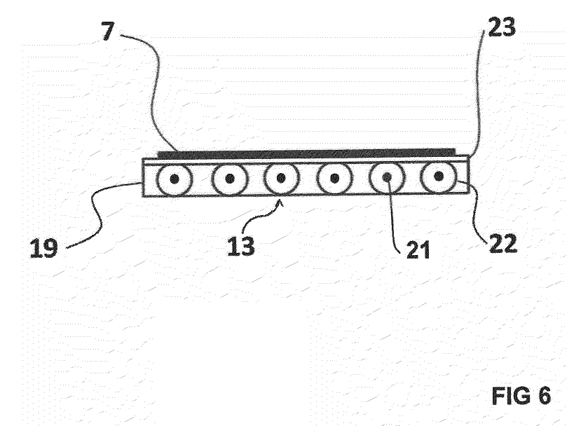

FIG. 6 depicts a loaded substrate tray.

The embodiment in FIG. 1 shows a detail of a basic embodiment of the drive unit for the purpose of a simultaneous, slip-free and synchronous drive of a plurality of identical drive rollers 1 and deflecting rollers 2. In a vacuum processing system a plurality of drive rollers 1 and deflecting rollers 2 are evenly spaced apart one after the other in a row. These drive rollers and deflecting rollers exhibit the same diameter and are, moreover, also constructed in the same way. To this end it is necessary that each of the deflecting rollers 2 and the drive rollers 1 exhibit twelve groups of three cylindrical nubs 3, said groups being distributed uniformly over the periphery. The nubs 3 of a group are evenly spaced apart from each other in the axial direction of the rollers 1, 2 and have the same position in the circumferential direction of the rollers 1, 2.

The traction element 4 of the drive unit is a continuous metal strip, which exhibits circular perforations 5. These perforations 5 are arranged in a way that corresponds to the nubs 3. That is, three perforations 5 at a time are evenly spaced apart from each other in the transverse direction of the traction element 4. Each such group of three perforations 6 is evenly spaced apart from each other in relation to the two neighboring groups of perforations 5 in the longitudinal direction of the traction element 4. The spacing between the perforations 5 in the longitudinal and transverse direction of the traction element 4 is equal to the spacing between the nubs 3 in the circumferential and/or axial direction of the rollers 1, 2 so that the nubs 3 can be moved so as to mesh with the perforations 5 and, thus, make possible a slip-free transfer of motion.

The linear arrangement of the deflecting rollers 2 and the drive rollers 1 makes it possible to drive simultaneously and synchronously all of the rollers 1, 2 with only one traction element 4 and without the use of additional tensioning or pressing rollers, since owing to the positive locking between the nubs 3 and the perforations 5, the traction element 4 does not have to be pressed against the periphery of the drive rollers 1, in order to increase the friction. Nevertheless, it may be practical for other embodiments to provide additional tensioning or pressing rollers, especially when, for example, the transport rollers do not mesh simultaneously with the upper and lower strand of the traction element 4, when the actual transport rollers do not exhibit nubs 3 or teeth, and/or when the traction element 4 is not perforated. The described drive unit is equally suitable for driving a planar arrangement of transport rolls for the transport of flat substrates, for the transport of carriers, for the movement of measurement instruments, and also for driving lift devices or storage units or other system components, wherein a transfer of motion takes place.

FIG. 2 shows an embodiment, in which the drive unit is a component of a transport device for tubular substrates inside a vacuum processing system, which is described in the patent application WO 2008/003792 A2.

The transport device comprises two drive units of the type described below and of which each transfers a motion to one end each of a tubular substrate 7. That is, the tubular substrates 7 that are to be transported are mounted with each of their two ends in one of the two drive units of the transport device. To this end, this transport device has one drive unit (of which one is shown in the figure) on each of the two sides along the transport path of the substrates 7 through the vacuum processing system. Each drive unit comprises two continuous conveyors—that is, two devices, each of which exhibits a continuous traction element 4, which is guided around at least two deflecting rollers 2. These two continuous conveyors are spaced apart from each other. Between the deflecting rollers 2 of the continuous conveyors the distance between the traction elements 4 is decreased owing to a plurality of pressing rollers 6. In this case the pressing rollers 6 are arranged alternatingly at the traction elements 4 of both continuous conveyors in such a manner that when the substrates move through the gap existing between the traction elements 4, the substrates 7 are moved upwards and downwards during the passage of the pressing rollers 6.

Owing to the pressing rollers 6 and the resulting decreased distance between the two traction elements 4 in relation to each other, the friction locking of the tubular substrates 7 with the two traction elements 4 is enhanced. If the rotational speed of the deflecting rollers 2 on the two continuous conveyors is the same and their direction of transport in relation to the substrates 7, enclosed between them, is in the same direction, then the tubular substrates 7 are put into translational motion along the direction of transport without rotation. If, in contrast, the rotational speed of the deflecting rollers 2 at the two continuous conveyors is the same, but their direction of transport in relation to the substrates 7, enclosed between them, is in opposite directions, then the tubular substrates 7 are put into just a rotational motion without translation. If the rotational speed of the deflecting rollers 2 of both continuous conveyors is different, then a combined translational and rotational motion of the substrates 7 takes place. In order to hold the tension of the traction elements 4 of both continuous conveyors constant, it is practical in this embodiment to mount in a springy manner at least one of the deflecting rollers 2 of each continuous conveyor. In the same way the pressing rollers 6 could also be mounted in a springy manner.

As apparent from the figure, the metal strips, used as the traction elements 4, are provided with perforations 5 in the same way as in the embodiment, according to FIG. 1. However, in this case only the deflecting rollers 2 are provided with nubs 3, but the pressing rollers 6 are not. In this case the deflecting rollers 2 transfer the motion of an electric motor (not illustrated) to the traction element 4, which in interaction with the other traction element 4 induces the transport of the tubular substrates 7 through the vacuum processing system. The pressing rollers 6 do not exhibit nubs, in order to avoid a direct contact between the nubs and the substrates 7. In the event that the pressing rollers 6 are mounted in a springy manner, then it is also necessary to dispense with the nubs, because the meshing with the perforations of the traction element 4 cannot be guaranteed.

FIG. 3 is a longitudinal view of a detail of a vacuum processing system. The depicted vacuum processing system is suitable for subjecting plate-like substrates—for example, flat glass plates—to multiple diffusion treatment steps in a continuous process, in order to produce, for example, thin layer solar cells having large surface area.

To this end, at one end of the vacuum processing system the substrates 7 are fed through a lock system (not illustrated) into the housing 8 of the vacuum processing system and then transported through the vacuum processing system on a transport device in the transport direction that is indicated by the arrows 16. In so doing, the substrates 7 pass through several alternatingly arranged transfer zones 9 and processing zones 10, in which the actual diffusion treatment of the substrates 7 occurs. Following the completion of all of the intended diffusion processes, the substrates 7 are removed from the housing 8 of the vacuum processing system through a lock system (not illustrated) at the other end of the vacuum processing system.

The subsection of the vacuum processing system that is depicted in the figure shows two processing zones 10, in which the substrates 7 are subjected to a variety of diffusion treatments. For this purpose, each processing zone 10 has a gas feed device 11, a heating system 12 as well as a vacuum pump 14. It must also be pointed out that the depiction of these components serves only for the purpose of illustration, since the manner of their arrangement is irrelevant for the technical solution that is proposed here and that the actual arrangement of these components in a real vacuum processing system for carrying out diffusion treatments may deviate significantly from the chosen illustration—a state, of which, however, the person skilled in this art is well aware in any event.

Moreover, in each of the two depicted processing zones 10 there is a storage unit, which is designed for receiving a plurality of substrates 7. To this end, the storage unit in the embodiment comprises six substrate trays 13, which are stacked one above the other. In the embodiment the number of substrate trays 13 is selected so low solely for reasons relating to a better overview. It is self-evident that this number can also be significantly larger. Precisely in the case of plate shaped substrates 7 of relatively thin thickness it is possible for a storage unit to comprise forty or even more substrate trays 13. In this context the productivity of the vacuum processing system increases with the number of substrate trays 13.

Furthermore, the storage unit comprises a drive unit, which makes it possible to raise or lower, as desired, the substrate trays 13 in the direction of lift 18, indicated by the double arrows. The drive unit comprises a traction element 4, which is guided around two deflecting rollers 2 and which is a continuous, perforated metal strip, as already described above. The substrate trays are operatively connected to the traction element 4 in such a manner that the substrate trays 13 are raised or lowered through the motion of the traction element 4. At the same time the drive unit can be actuated in such a manner that each substrate tray 13 can be stopped in the plane of transport—that is, the plane, in which the substrates 7 lie when transported through the transfer zones 9. This stoppage can be achieved in that the drive unit comprises a stepping motor (not illustrated) as the drive mechanism.

In this way it is possible to load the substrate trays 13 with substrates 7 from an upstream transport device and to unload onto a downstream transport device. In order to facilitate this procedure, a loading and/or unloading device can be provided at the substrate trays 13 and/or between the transfer zone 9 and the processing zone 10 in order to load and/or unload the storage unit. For reasons relating to a better overview the embodiment dispenses with a graphical rendering of the loading and/or unloading devices. In this context the loading and/or unloading devices may be, for example, robot arms, which assist the substrates 7 during the transition from the transfer zone 9 into the processing zone 10 or vice versa, and which are arranged, for example, in precisely this transition zone. However, each substrate tray 13 can also exhibit its own loading and/or unloading device, which in turn can be designed, for example, as a drive unit of the above described kind—that is, with a traction element 4, which is guided around at least two deflecting rollers 2 and which is a continuous, perforated metal strip.

In order to transport the substrates 7, the transfer zones 9 have transport devices, which are also designed as the above described drive units with deflecting rollers 2, drive rollers 1 and a traction element 4, which is designed as a perforated metal strip. Lying on the traction elements 4, the substrates are transported through the transfer zone 9 until a processing zone 10 is reached. In this processing zone the substrate 7 is loaded onto an available substrate tray 13. Thereupon the storage unit is moved by means of the drive unit—that is, the substrate trays 13 are raised or lowered until the next substrate tray 13 is in the transport plane and then the procedure is repeated for the next substrate 7. In the same way the substrate 7 that was located previously in the substrate tray 13 is unloaded onto the downstream transport device before or simultaneously with the next sequential substrate 7, so that the substrate tray 13 is free for the next substrate 7, which moves up in line and is made available on the upstream transport device.

Since each processing zone 10 of the vacuum processing system has a storage unit, it is possible, on the one hand, to significantly shorten the length of the processing zone 10, as seen in the direction of transport 17 of the substrates 7, as compared to a simple sequential continuous process, because during the diffusion treatment the substrates 7 are not moved at all in the direction of transport 17. On the other hand, the diffusion treatment of a plurality of substrates 7 can take place in a very confined space, because the substrates 7 in a storage unit are held simultaneously in the processing zone 10.

In this way the proposed embodiments of transport devices, drive units and vacuum processing systems, make it possible to subject substrates with high productivity, in a confined space and in a semi-continuous process, to one or more diffusion treatment(s) without having to interrupt the process.

The substrate tray 13 in FIGS. 4 to 6 is a component of a storage unit, as shown inside the processing system in FIG. 4.

The substrate tray 13 comprises a frame 19, a substrate tray area 23 and a plurality of drivable supporting elements 20, which are mounted in a rotatable manner in the frame 19, for the purpose of receiving a substrate 7. The substrate tray area 23 exhibits a plurality of recesses 24, and the supporting elements 20, which are rollers 22 in the embodiment and which are mounted on shafts 21 and which are mounted in a rotatable manner with the shaft 21 in the frame 19, are mounted in a movable manner perpendicularly to the substrate tray area 23, so that in a first position they are arranged below the substrate tray area 23 and in a second position they project upwards through the substrate tray area 23.

For the sake of a better overview, FIG. 4 shows only one shaft 21 with the mounted support elements 20, which are designed as rollers 22 in the embodiment. However, FIGS. 5 and 6 show that the substrate tray area 13 has several shafts 21, which are distributed over the substrate tray area 23 and which bear the support elements 20.

It is especially clear from FIG. 2 that the support elements 20—that is, the rollers 22—can receive the substrate 7, which has been moved up in the direction of transport 17, in the second position and can transport said substrate into a position, in which the substrate 7 is arranged above the substrate tray 13.

When the substrate 7 has reached this position, the rollers 22 can be lowered, so that the substrate 7 lies on the substrate tray area 23. Then the substrate tray 13 can be raised or lowered, so that the substrate tray 13 together with the substrate 7 is moved out of the transport plane.

1. Drive unit for a system component of a vacuum processing system, comprising a traction element, guided around at least two deflecting rollers, wherein the traction element comprises a continuous metal strip.

2. Drive unit, as claimed in claim 1, wherein the metal strip comprises stainless steel.

3. Drive unit, as claimed in claim 1, wherein the traction element has perforations evenly spaced apart in a longitudinal direction of the traction element, and at least one deflecting roller has nubs or teeth uniformly distributed over a periphery of the at least one deflecting roller, so that the nubs or the teeth mesh with the perforations.

4. Drive unit, as claimed in claim 3, wherein at least two perforations are provided side by side in a transverse direction of the traction element, and in a corresponding manner at least two nubs or teeth are provided side by side in an axial direction of the at least one deflecting roller.

5. Drive unit, as claimed in claim 3, wherein the perforations are circular and the nubs are cylindrical.

6. Transport device for a vacuum processing system, comprising: at least two sequentially operating transport devices for transport of single substrates through the vacuum processing system, and a storage unit for receiving a plurality of substrates provided in at least one processing zone of the vacuum processing system, and wherein the storage unit is loaded with substrates from an upstream sequential transport device and unloaded of substrates onto a downstream sequential transport device.

7. Transport device, as claimed in claim 6, further comprising a loading and/or unloading device for loading and/or unloading the storage unit.

8. Transport device, as claimed in claim 6, wherein the storage unit has at least two substrate trays, and at least one substrate tray is moved back and forth between a receiving position and a storage position.

9. Transport device, as claimed in claim 8, further comprising a drive unit for driving the at least one substrate tray back and forth between the receiving position and the storage position, the drive unit comprising a traction element guided around at least two deflecting rollers, the traction element comprising a continuous metal strip.

10. Transport device, as claimed in claim 8, wherein the at least one substrate tray is moved essentially at right angles to a direction of motion of the upstream or the downstream transport device.

11. Transport device, as claimed in claim 6, wherein the substrate tray is configured for receiving simultaneously at least two substrates.

12. Transport device, as claimed in claim 6, wherein the at least one upstream or downstream transport device comprises a traction element guided around at least two deflecting rollers, the traction element comprising a continuous metal strip.

13. Vacuum processing system comprising a vacuum chamber; at least one treatment device for vacuum treatment of substrates; an upstream transport device, upstream of the at least one treatment device; a downstream transport device, downstream of the treatment device, a storage unit for receiving at least two substrates in a zone of the treatment device, and the storage unit being loaded with substrates from the upstream transport device and unloaded of substrates onto the downstream transport device.

14. Vacuum processing system, as claimed in claim 13, further including a loading and/or unloading device for loading and/or unloading the storage unit.

15. Vacuum processing system comprising a vacuum chamber, at least one treatment device fore vacuum treatment of substrates, and an additional system component with a drive unit as claimed in claim 1.

16. Vacuum processing system, as claimed in claim 15, wherein the traction element is electrically wired.

17. Vacuum processing system, as claimed in claim 15, wherein the additional system component comprises a transport device for substrates or carriers.

18. Vacuum processing system, as claimed in claim 15, wherein the additional system component comprises a lift mechanism.

19. Vacuum processing system, as claimed in claim 15, wherein the additional system component comprises a storage unit.

20. Vacuum processing system, as claimed in claim 15, wherein the additional system component is mounted totally or partially on an atmospheric side of the vacuum chamber.

21. Transport device for a vacuum processing system, comprising at least two transport devices for sequential transport of single substrates through the vacuum processing system, a storage unit for receiving a plurality of substrates in at least one processing zone of the vacuum processing system, and the storage unit being loaded with substrates from an upstream transport device for the sequential transport of substrates and being unloaded of substrates onto a downstream transport device for the sequential transport of substrates, the storage unit having at least two substrate trays, at least one substrate tray being moved back and forth between a receiving position and a storage position, the at least one substrate tray comprising a frame and a plurality of drivable support elements mounted in a rotatable manner in the frame, for receiving a substrate.

22. Transport device, as claimed in claim 21, wherein the support elements comprise rollers.

23. Transport device, as claimed in claim 21, wherein the support elements comprise a plurality of rollers mounted on a shaft.

24. Transport device, as claimed in claim 21, wherein the substrate tray has a substrate tray area with recesses for the support elements.

25. Transport device, as claimed in claim 24, wherein the support elements are moved relative to the frame in such a manner that, in a first position, the support elements are arranged totally below the substrate tray area and, in a second position, the support elements protrude at least partially through the recesses and over the substrate tray area.

26. Vacuum processing system comprising a transport device, as claimed in claim 21.
